(19) United States
(12) Patent Application Publication
(10) Pub. No.: US 2025/0239455 A1
(43) Pub. Date: Jul. 24, 2025

(54) SUBSTRATE PROCESSING METHOD AND SUBSTRATE PROCESSING APPARATUS

(71) Applicant: SCREEN Holdings Co., Ltd., Kyoto (JP)

(72) Inventors: Tsungju LIN, Kyoto (JP); Hiroaki ISHII, Kyoto (JP)

(21) Appl. No.: 18/848,121

(22) PCT Filed: Nov. 25, 2022
(86) PCT No.: PCT/JP2022/043551

§ 371 Date: Sep. 17, 2024

(30) Foreign Application Priority Data
Mar. 18, 2022 (JP) 2022-043699

(51) Int. Cl. H01L 21/306; B24B 37/04

(52) U.S. Cl. CPC H01L 21/30625; B24B 37/042

(57) ABSTRACT

The present invention relates to a substrate processing method and a substrate processing apparatus. A substrate processing method includes:
a substrate rotating step of rotating a substrate made of silicon in a horizontal orientation;
a chemical liquid mixture discharging step of causing a chemical liquid nozzle to discharge a chemical liquid mixture including hydrofluoric acid and ozonated water onto a rear surface of the substrate being rotated;
a polishing tool pressing step of pressing a polishing tool that has a resin body including dispersed abrasive grains, against the rear surface of the substrate being rotated, while causing a fixed nozzle to discharge a rinsing liquid onto the rear surface of the substrate being rotated, after the chemical liquid mixture discharging step; and
a polishing tool moving step of moving the polishing tool between a center of the substrate and a perimeter of the substrate while the polishing tool pressing step is being performed.

### TECHNICAL FIELD

The present invention relates to a substrate processing method and a substrate processing apparatus for processing a substrate. Examples of the substrate include a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### BACKGROUND ART

A conventional substrate processing apparatus includes a holding and rotating unit that rotates a substrate held in the horizontal orientation, a brush arm, a chemical liquid arm, and a pure water nozzle that discharges pure water (see, for example, Patent Literature 1 and Patent Literature 2). The brush arm includes a brush that is brought into contact with a surface of the substrate, and cleans the surface with the brush. The chemical liquid arm includes a chemical liquid nozzle through which a chemical liquid is discharged.

Patent Literature 3 discloses a cylindrical polishing head made with polyvinyl alcohol (PVA) sponge having abrasive grains dispersed therein, for example. Patent Literature 4 discloses surface processing with dry chemical mechanical grinding. In this processing, an artificial grindstone including abrasive (abrasive grains) fixed thereto with a resin binder is used.

### CITATION LIST

### Patent Literature

Patent Literature 1: JP 2017-183711 A
Patent Literature 2: JP 2017-175062 A
Patent Literature 3: JP 2018-046109 A
Patent Literature 4: JP 6779540 B1

### SUMMARY OF INVENTION

### Technical Problem

However, the conventional substrate processing apparatuses have following problems. In recent years, there has been a problem of defocus of an extreme ultraviolet (EUV) exposure device (what is called being out of focus) due to poor substrate flatness of a rear surface of a substrate (e.g., a wafer). One of the causes of poor flatness is a chuck mark, which becomes attached (formed) when the rear surface of the substrate is suctioned by a chuck. Chuck marks are generally classified into two types. The first type is a scratch or a pit formed when particles, such as metal dust, become nipped between the substrate and the chuck. The second type is a particle having been firmly attached to the substrate, having been attached when the particle become buried into the substrate W as the particle becomes nipped between the substrate and the chuck. With the conventional cleaning methods, only a small proportion of such chuck marks can be removed, disadvantageously.

According to Patent Literature 1 and Patent Literature 2, a chemical liquid mixture (FOM) that is a mixture of hydrofluoric acid solution and ozonated water is discharged onto a substrate, and the substrate is then cleaned with a brush while supplying deionized water (DIW) onto the substrate. For the brush, a sponge-like scrubbing member made of polyvinyl alcohol (PVA) is used. However, even with this method, there are cases in which only a small proportion of the chuck marks is removable.

The present invention has been made in view of the situation described above, and an object of the present invention is to provide a substrate processing method and a substrate processing apparatus capable of removing a larger proportion of chuck marks.

### Solution to Problem

In order to achieve such an object, the present invention utilizes the following configurations. That is, a substrate processing method according to the present invention includes: a substrate rotating step of rotating a substrate made of silicon in a horizontal orientation; a chemical liquid mixture discharging step of causing a chemical liquid nozzle to discharge a chemical liquid mixture including hydrofluoric acid and ozonated water onto a rear surface of the substrate being rotated; a polishing tool pressing step of pressing a polishing tool that has a resin body including dispersed abrasive grains, against the rear surface of the substrate being rotated, while causing a rinsing liquid nozzle to discharge a rinsing liquid onto the rear surface of the substrate being rotated, after the chemical liquid mixture discharging step; and a polishing tool moving step of moving the polishing tool between a center of the substrate and a perimeter of the substrate while the polishing tool pressing step is being performed.

With the substrate processing method according to the present invention, the silicon oxidizes with the ozonated water, and the oxide film (SiO) is etched with hydrofluoric acid, as the chemical liquid mixture (FOM) is discharged onto the rear surface of the substrate. As a result, fine scratches and pits on the rear surface of the substrate can be eliminated. In addition, because the parts around the particles having been firmly attached to the rear surface of the substrate are etched with the chemical liquid mixture, the particles are made more easily removable. The rear surface of the substrate is then actively polished (ground) using the polishing tool. Therefore, the particles become more easily removable from the rear surface of the substrate. Hence, it is possible to remove a larger proportion of the chuck marks on the substrate.

In addition, the chemical liquid mixture can reduce the surface roughness on the rear surface of the substrate. Therefore, less load is required in the polishing process for removing scratches and the like remaining from the etching of the chemical liquid mixture.

The substrate processing method described above preferably further includes a second chemical liquid mixture discharging step of causing the chemical liquid nozzle to discharge the chemical liquid mixture onto the rear surface of the substrate that is being rotated, again, after the polishing tool pressing step and the polishing tool moving step. Although chuck marks on the rear surface of the substrate can be removed by polishing, the scratches formed by the polishing tool may remain unremoved. Therefore, by discharging the chemical liquid mixture onto the rear surface of the substrate after the polishing (the polishing tool pressing step and the polishing tool moving step), it becomes possible to remove the scratches formed by the polishing tool.

In the second chemical liquid mixture discharging step of the substrate processing method described above, the chemical liquid nozzle is preferably moved between above the center of the substrate and above the perimeter of the substrate while the chemical liquid nozzle is discharging the chemical liquid mixture. Although the chemical liquid mixture can remove the scratches formed by the polishing tool, if the chemical liquid mixture from the chemical liquid nozzle is kept landing on the same position on the rear surface of the substrate, etching may proceed too far, at that position. Therefore, by moving the position of the chemical liquid mixture, it is possible to prevent the etching from proceeding locally on the rear surface of the substrate, the rear surface having been planarized by the polishing.

A substrate processing apparatus according to the present invention includes: a holding and rotating unit that holds and rotates a substrate made of silicon in a horizontal orientation; a chemical liquid nozzle that discharges a chemical liquid mixture including hydrofluoric acid and ozonated water; a rinsing liquid nozzle that discharges a rinsing liquid; a polishing tool that has a resin body including dispersed abrasive grains; a polishing tool moving mechanism that moves the polishing tool; and a control unit, in which: the control unit causes the holding and rotating unit to rotate the substrate; the control unit causes the chemical liquid nozzle to discharge the chemical liquid mixture onto a rear surface of the substrate being rotated; after the chemical liquid mixture is discharged, the control unit causes the polishing tool moving mechanism to press the polishing tool against the rear surface of the substrate being rotated, while causing the rinsing liquid nozzle to discharge the rinsing liquid onto the rear surface of the substrate being rotated; and the control unit further causes the polishing tool moving mechanism to move the polishing tool between a center of the substrate and a perimeter of the substrate while pressing the polishing tool against the rear surface of the substrate being rotated.

### Advantageous Effects of Invention

With the substrate processing method and the substrate processing apparatus according to the present invention, it is possible to remove a larger proportion of the chuck marks.

### BRIEF DESCRIPTION OF DRAWINGS

FIG. 1 is a diagram illustrating a schematic configuration of a substrate processing apparatus according to a first embodiment.

FIG. 2 is a plan view of the substrate processing apparatus according to the first embodiment.

FIG. 3 is a flowchart for explaining an operation of the substrate processing apparatus according to the first embodiment.

FIG. 4(a) is a plan view for explaining a FOM discharging step; FIG. 4(b) is a side view of FIG. 4(a); FIG. 4(c) is a plan view for explaining an ozonated water discharging step; FIG. 4(d) is a side view of FIG. 4(c); FIG. 4(e) is a plan view for explaining a rinsing step; and FIG. 4(f) is a side view of FIG. 4(e).

FIG. 5 is a side view illustrating the path of the movement of the polishing tool repeating the polishing.

FIGS. 6(a) to 6(e) are schematics for explaining how a chuck mark on the rear surface of the substrate is removed.

FIG. 7 is a flowchart for explaining an operation of a substrate processing apparatus according to a second embodiment.

FIG. 8 is a graph illustrating thicknesses of a substrate before and after an etching process that uses the FOM.

FIG. 9 is a side view for explaining an operation of moving a chemical liquid nozzle while discharging the FOM from the chemical liquid nozzle, in a second FOM discharging step according to a modification.

### FIRST EMBODIMENT

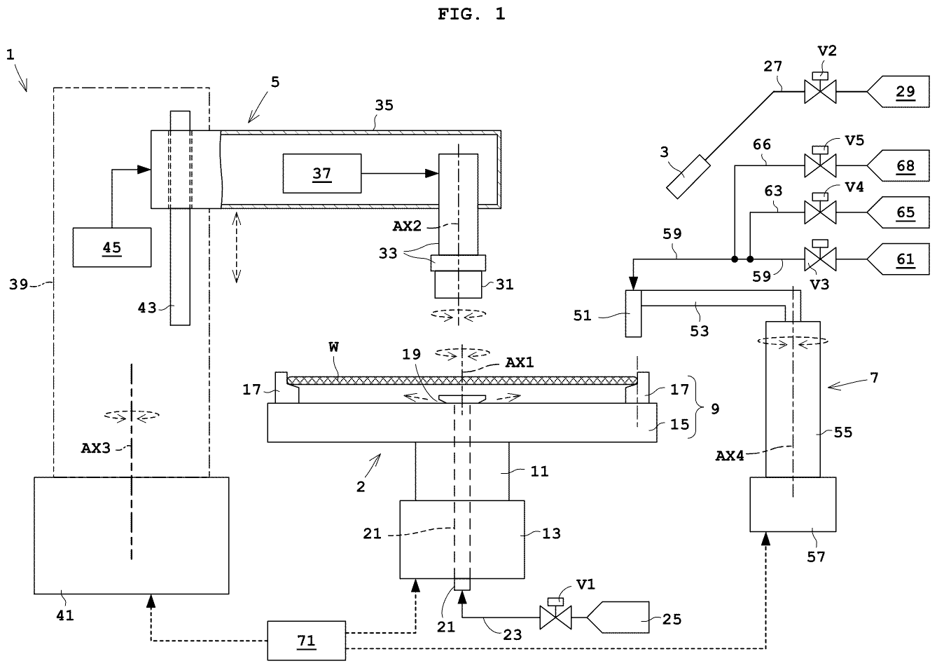

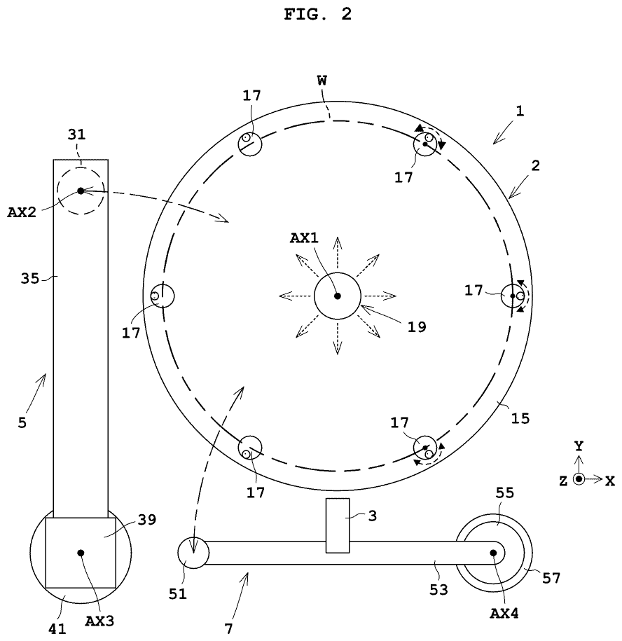

A first embodiment of the present invention will now be described with reference to drawings. FIG. 1 is a diagram illustrating a schematic configuration of a substrate processing apparatus according to the first embodiment. FIG. 2 is a plan view of the substrate processing apparatus according to the first embodiment.

### (1) Configuration of Substrate Processing Apparatus

A configuration of the substrate processing apparatus 1 will be described with reference to FIGS. 1 and 2. The substrate processing apparatus 1 includes a holding and rotating unit 2, a fixed nozzle 3, a polishing arm 5, and a chemical liquid arm 7. The holding and rotating unit 2 holds and rotates the substrate W in a horizontal orientation. Note that the substrate (silicon substrate) W is made of silicon (Si), and has a disk-like shape. In this embodiment, the diameter of the substrate W is 300 mm as an example, but is not limited to this size.

The holding and rotating unit 2 includes a spin chuck 9, a rotation shaft 11, and a rotation drive unit 13. The rotation drive unit 13 includes an electric motor. The rotation drive unit 13 rotates the spin chuck 9 about a vertical axis AX1 via the rotation shaft 11.

The spin chuck 9 includes a spin base 15 and three or more (e.g., six) holding pins 17. The spin base 15 has a disk-like shape. The vertical axis AX1 passes through the center of the spin base 15. The three or more holding pins 17 stand upright in a ring-like shape, at equal intervals around the vertical axis AX1. Some or all of the three or more holding pins 17 are configured to be movable. Each of the holding pins 17 that are movable rotates about its vertical axis passing therethrough. With this, the spin chuck 9 holds the substrate W by holding the side surface of the substrate W with the three or more holding pins 17. The spin chuck 9 may also be configured to hold the substrate W by suctioning the bottom surface of the substrate W.

The holding and rotating unit 2 includes a gas outlet 19, a gas feeder pipe 21, a gas delivery pipe 23, a gas source 25, and an on-off valve V1. The gas outlet 19 has a ring-shaped slit, and discharges gas substantially in the entire horizontal directions from the vertical axis AX1. The gas feeder pipe 21 sends gas to the gas outlet 19. The gas feeder pipe 21 is provided in a manner penetrating the rotation shaft 11 and the rotation drive unit 13 along the vertical axis AX1.

The gas delivery pipe 23 delivers the gas (e.g., an inert gas such as nitrogen) from the gas source 25 to the gas feeder pipe 21. The on-off valve V1 is provided to the gas delivery pipe 23. While the on-off valve V1 is open, the gas is discharged from the gas outlet 19. When the on-off valve V1 is closed, the gas outlet 19 stops discharging gas. The gas outlet 19 discharges the gas in such a manner that the gas flows from the center of the substrate W toward the perimeter (outer edge) of the substrate W, inside the space between the substrate W and the spin base 15.

The fixed nozzle 3 discharges pure water (rinsing liquid) diagonally downwards with respect to the top surface of the substrate W. As the pure water, deionized water (DIW) is used, for example. The fixed nozzle 3 is provided at a fixed position offset from the center of the substrate W. The position where the fixed nozzle 3 is fixed is such a position that the movements of a polishing tool 31 and a chemical liquid nozzle 51, which will be described later, are not obstructed. In this embodiment, the fixed nozzle 3 is provided outside the substrate W held by the holding and rotating unit 2. As illustrated in FIG. 2, the fixed nozzle 3 is provided between a polishing tool turning mechanism 41 and a nozzle turning mechanism 57, which will be described later. The fixed nozzle 3 is configured not to move in the horizontal direction, but may also be configured movable in the horizontal direction. The fixed nozzle 3 may also be configured not to be turned about a predetermined vertical axis, or may be configured not to be moved up or down. The fixed nozzle 3 corresponds to a rinsing liquid nozzle according to the present invention.

A tip end of a pure water pipe 27 is connected to the fixed nozzle 3. A base end of the pure water pipe 27 is connected to a pure water source 29. The pure water pipe 27 sends pure water from the pure water source 29 into the fixed nozzle 3. The pure water pipe 27 has an on-off valve V2. While the on-off valve V2 is open, the pure water is discharged from the fixed nozzle 3. When the on-off valve V2 is closed, the fixed nozzle 3 stops discharging the pure water.

The polishing arm 5 is a mechanism for polishing the rear surface (top surface) of the substrate W. The polishing arm 5 includes a polishing tool 31, a shaft 33, a polishing arm body 35, and an electric motor 37. The polishing tool 31 is also referred to a brush or a polishing brush.

The polishing tool 31 polishes the rear surface of the substrate by making use of the chemical action on the surface, or using an approach referred to as chemical mechanical grinding (CMG). The polishing tool 31 has a columnar shape. The polishing tool 31 has a resin body including abrasive grains (polishing material) dispersed therein. In other words, the polishing tool 31 is formed by fixing abrasive grains with a resin binder. For example, the polishing tool 31 has PVA including silicon carbide (SiC) dispersed therein, as abrasive grains.

The polishing tool 31 may also be configured in the manner described below. As the abrasive grains, an oxide such as cerium oxide (CeO₂) or silica (SiO₂) may be used, for example. The average grain size of the abrasive grains is preferably 10 μm or smaller. As the resin body (resin binder), a thermosetting resin such as an epoxy resin or a phenol resin may be used, for example. As the resin body, a thermoplastic resin such as ethyl cellulose may be used, for example. With a thermoplastic resin, polishing is performed so as not to cause softening of the thermoplastic resin.

The chemical mechanical grinding (CMG) will now be described. The CMG theoretically takes place in accordance with the following principle. As abrasive grains such as cerium oxide and an object come into contact, a high temperature and a high pressure are generated near the abrasive grains, and cause a solid phase reaction between the abrasive grains and the object, to generate silicates. As a result, the surface layer of the object becomes softened, and the softened surface layer is mechanically removed by the abrasive grains.

The description now goes back to the polishing arm 5. The upper end of the polishing tool 31 is attached to the lower end of the shaft 33 extending in the vertical direction. The shaft 33 has an upper portion held rotatably about a vertical axis AX2 by the polishing arm body 35 extending in the horizontal direction. The electric motor 37 rotates the shaft 33 about the vertical axis AX2 via a belt or a gear, for example. The polishing tool 31 and the shaft 33 are provided on the tip-end side of the polishing arm body 35.

The polishing arm 5 further includes a lift mechanism (linear actuator) 39 and a polishing tool turning mechanism 41. The lift mechanism 39 moves elements such as the polishing tool 31 and the polishing arm body 35 up and down. The lift mechanism 39 includes a guide rail 43 and a drive unit 45. The guide rail 43 supports the base end of the polishing arm body 35 in a manner up and down movable. The guide rail 43 guides the polishing arm body 35 in the up and down directions. The drive unit 45 includes, for example, an electric motor and a screw shaft.

Note that the drive unit 45 may include an air cylinder and an electropneumatic regulator, instead of the electric motor or the like. The electropneumatic regulator supplies gas such as air at a pressure set on the basis of an electric signal from the control unit 71, to be described later, to the air cylinder.

The polishing tool turning mechanism 41 is provided outside the substrate W being held by the holding and rotating unit 2. The polishing tool turning mechanism 41 turns the polishing tool 31, the polishing arm body 35, the lift mechanism 39, and the like about a vertical axis AX3. The polishing tool turning mechanism 41 includes an electric motor. As illustrated in FIG. 2, a standby position of the polishing tool 31 is positioned in the +Y direction of the polishing tool turning mechanism 41. The lift mechanism 39 and the polishing tool turning mechanism 41 correspond to the polishing tool moving mechanism according to the present invention.

The chemical liquid arm 7 includes a chemical liquid nozzle 51, an arm body 53, a turning shaft 55, and a nozzle turning mechanism 57. The chemical liquid nozzle 51 discharges the chemical liquid downwards onto the top surface of the substrate W. The chemical liquid nozzle 51 selectively discharges FOM, ozonated water (O₃), and pure water, for example. The FOM is a chemical liquid mixture of hydrofluoric acid (HF) and ozonated water (O₃). The ratio of the hydrofluoric acid and the ozonated water in the FOM is 1:7.

A tip end of a chemical liquid pipe 59 is connected to the chemical liquid nozzle 51. A base end of the chemical liquid pipe 59 is connected to a FOM source 61. The chemical liquid pipe 59 sends FOM from the FOM source 61 to the chemical liquid nozzle 51. The chemical liquid pipe 59 is provided with an on-off valve V3. When the on-off valve V3 is open and the on-off valves V4, V5, which will be described later, are closed, the FOM is discharged from the chemical liquid nozzle 51. When the on-off valve V3 is closed, the chemical liquid nozzle 51 stops discharging the FOM.

A tip end of an ozonated water pipe 63 is communicably connected to the chemical liquid pipe 59, at a position between the chemical liquid nozzle 51 and the on-off valve V3. A base end of the ozonated water pipe 63 is connected to an ozonated water source 65. The ozonated water pipe 63 sends the ozonated water from the ozonated water source 65 to the chemical liquid nozzle 51, via the chemical liquid pipe 59. The ozonated water pipe 63 is provided with an on-off valve V4. The on-off valve V4 controls to discharge the ozonated water from the chemical liquid nozzle 51, and to stop discharging the ozonated water.

The tip end of a second pure water pipe 66 is communicably connected to the chemical liquid pipe 59, at a position between the chemical liquid nozzle 51 and the on-off valve V3. A base end of the second pure water pipe 66 is connected to a second pure water source 68. The second pure water pipe 66 sends the pure water (e.g., DIW) from the second pure water source 68 to the chemical liquid nozzle 51, via the chemical liquid pipe 59. The second pure water pipe 66 is provided with an on-off valve V5. The on-off valve V5 controls to discharge the pure water from the chemical liquid nozzle 51 and to stop the discharging the pure water.

The chemical liquid pipe 59, the ozonated water pipe 63, and the second pure water pipe 66 are disposed in a manner passing through the inside of the arm body 53 and inside of the turning shaft 55.

The chemical liquid nozzle 51 is provided at a tip end of the arm body 53. The arm body 53 extends in the horizontal direction. A base end of the arm body 53 is connected to an upper portion of the turning shaft 55. The turning shaft 55 extends in the vertical direction. The nozzle turning mechanism 57 is provided under the turning shaft 55.

The nozzle turning mechanism 57 includes an electric motor. When the nozzle turning mechanism 57 causes the turning shaft 55 to rotate about a vertical axis AX4, the chemical liquid nozzle 51 and the arm body 53 are caused to turn about the vertical axis AX4. It is also possible for the chemical liquid arm 7 to include an electric motor for moving the chemical liquid nozzle 51 up and down.

In FIG. 2, the standby position of the chemical liquid nozzle 51 is at a position near the polishing tool turning mechanism 41, and in the −X direction of the nozzle turning mechanism 57. When the polishing tool 31 and the chemical liquid nozzle 51 are at their standby positions, the polishing arm 5 and the chemical liquid arm 7 are disposed in an L shape in plan view, as illustrated in FIG. 2.

The description will now return to FIG. 1. The substrate processing apparatus 1 includes a control unit 71 and a storage unit (not illustrated). The control unit 71 controls each component included in the substrate processing apparatus 1. The control unit 71 includes one or more processors such as a central processing unit (CPU). The storage unit includes at least one of a read-only memory (ROM), a random-access memory (RAM), and a hard disk, for example. The storage unit stores therein a computer program required in controlling each of the components included in the substrate processing apparatus 1.

### (2) Operation of Substrate Processing Apparatus 1 (Rear Surface Cleaning)

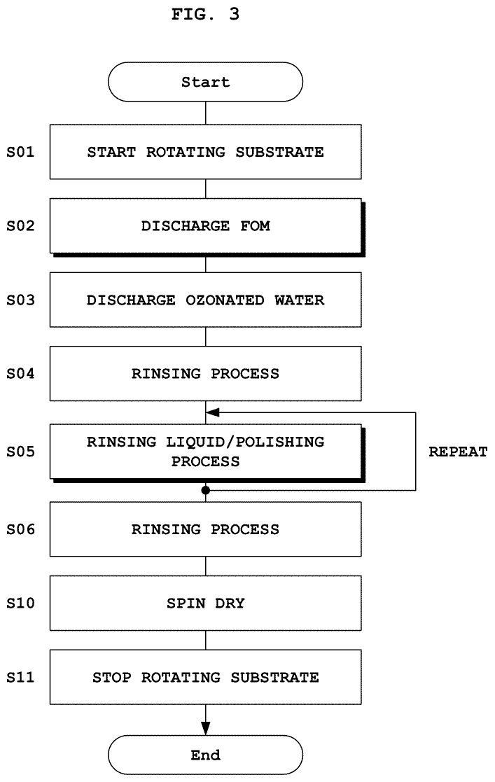

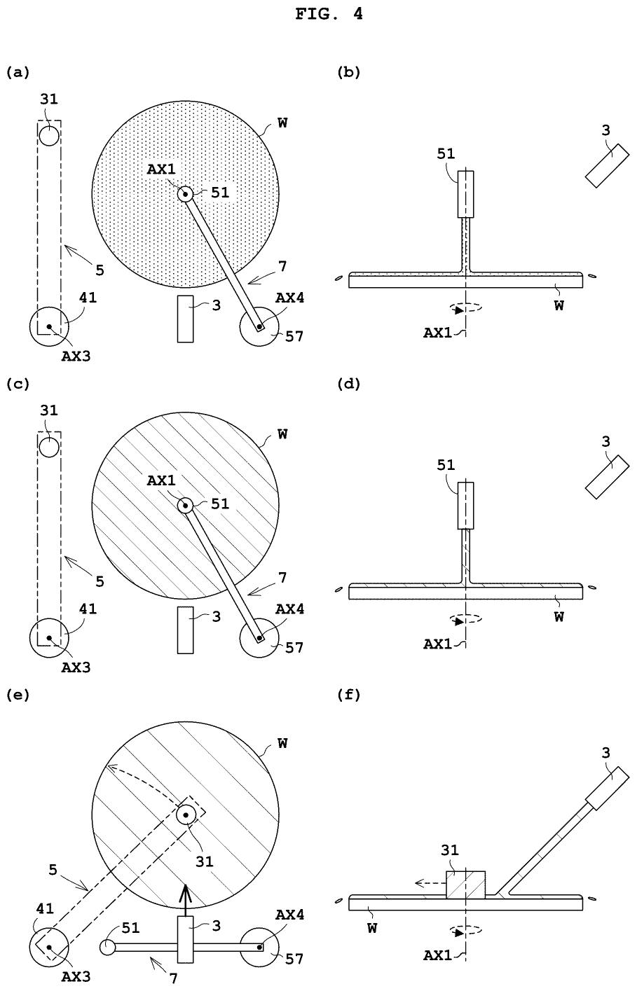

An operation of the substrate processing apparatus 1 will now be described with reference to the flowchart illustrated in FIG. 3. FIGS. 4(a) to 4(f), 5, and 6(a) to 6(e) are diagrams for explaining the operation of the substrate processing apparatus 1. Note that the rear surface of the substrate W refers to the surface without any electronic circuit, with respect to a front surface having electronic circuits (device surface) on the substrate W.

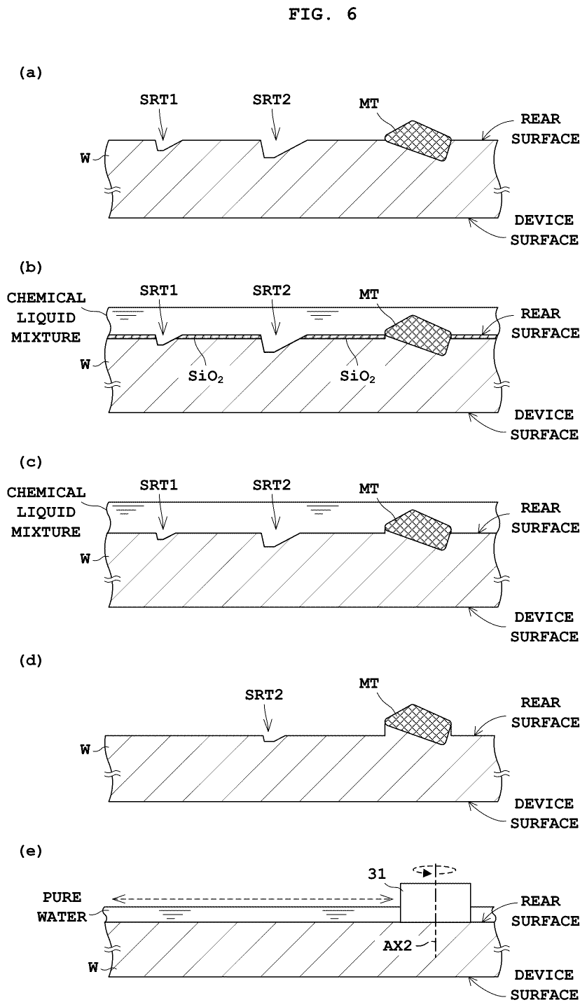

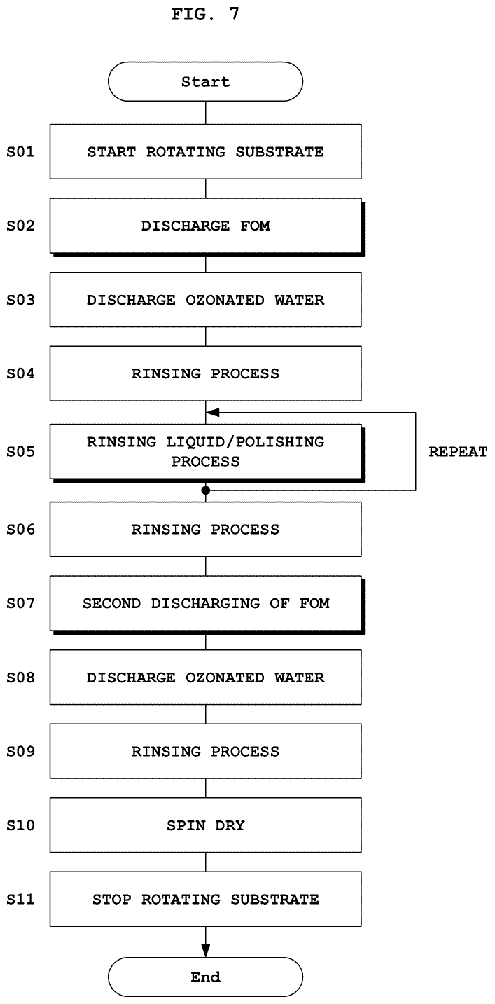

A transfer robot, not illustrated, transfers the substrate W with the rear surface facing upwards, onto the holding and rotating unit 2. The holding and rotating unit 2 then holds the substrate W having been transferred. As illustrated in FIG. 6(a), for example, there are a fine scratch (or pit) SRT1, a deeper scratch (or pit) SRT2, and a particle (metal dust) MT stuck on the rear surface of the substrate W.

After the substrate W is held, the on-off valve V1 is operated to open. As a result, the gas is discharged from the gas outlet 19 in a manner flowing from the center of the substrate W toward the perimeter (outer edge) of the substrate W, inside the space between the substrate W and the spin base 15. In this manner, it is possible to prevent the FOM or the like from reaching the bottom surface (device surface) of the substrate W, for example.

### [Step S01] Start Rotating Substrate

The holding and rotating unit 2 rotates the substrate W in a horizontal orientation. The substrate W is rotated about the vertical axis AX1. The substrate W is kept being rotated between steps S01 to S10.

### [Step S02] Discharge FOM

In steps S02 to S04, the substrate W is rotated at 800 rpm, for example. The nozzle turning mechanism 57 of the chemical liquid arm 7 moves the chemical liquid nozzle 51 from the standby position outside the substrate W to above the center of the substrate W. The control unit 71 then causes the chemical liquid nozzle 51 to discharge FOM (chemical liquid mixture of hydrofluoric acid and ozonated water) onto the rear surface (top surface) of the substrate W being rotated (see FIGS. 4(a) and 4(b)). At this time, the on-off valve V3 is operated to open, and the two on-off valves V4 and V5 are operated to close. The FOM having landed on the substrate W, which is being rotated, spreads across the entire surface of the substrate W, and extra FOM is removed off of the substrate W.

When the FOM is discharged to the rear surface (top surface) of the substrate W being rotated, the ozonated water in the FOM oxidizes the bare silicon (silicon) making up the substrate W (see FIG. 6(b)). In addition, hydrofluoric acid in the FOM etches the oxide film on the substrate W (see FIG. 6(c)). In other words, the FOM enables the oxide film to be removed while oxidizing the bare silicon into the oxide film. Furthermore, the oxide film and the nitride film having become attached on the rear surface of the substrate W before the FOM is discharged in step S02 are also made removable. Therefore, etching into the bare silicon making up the substrate W is also made possible. As a result, fine scratches and dents on the top surface (rear surface) of the substrate W can be removed (see FIG. 6(d)). In addition, the surface roughness of the rear surface of the substrate W can be reduced.

### [Step S03] Discharge Ozonated Water

The chemical liquid nozzle 51 is kept above the center of the substrate W. After the FOM is discharged from the chemical liquid nozzle 51 over a preset time period, the control unit 71 operates the on-off valve V4 to open and operates the two on-off valves V3 and V5 to close. As a result, ozonated water is discharged from the chemical liquid nozzle 51 to the rear surface of the substrate W (see FIGS. 4(c) and 4(d)). The ozonated water having landed on the rear surface of the substrate W spreads across the entire surface of the substrate W, and extra liquid is removed off of the substrate W, by the rotation of the substrate W. The ozonated water can make the rear surface of the substrate W hydrophilic; therefore, it is possible to prevent foreign substances from attaching again.

### [Step S04] Rinsing Process

The chemical liquid nozzle 51 is kept above the center of the substrate W. After the ozonated water is discharged from the chemical liquid nozzle 51 for a preset time period, the control unit 71 operates the on-off valve V5 to open and operates the two on-off valves V3 and V4 to close. As a result, pure water (e.g., DIW) is discharged from the chemical liquid nozzle 51 onto the rear surface of the substrate W. As a result, the ozonated water or the like on the substrate W is washed off of the substrate W.

The control unit 71 then operates the three on-off valves V3, V4, and V5 to close. The chemical liquid nozzle 51 stops discharging the pure water, accordingly. The nozzle turning mechanism 57 then moves the chemical liquid nozzle 51 from above the center of the substrate W to the standby position outside the substrate W.

### [Step S05] Rinsing Liquid/Polishing (Grinding) Process

After the chemical liquid nozzle 51 stops discharging pure water, the substrate W is rotated at 500 rpm, for example. The control unit 71 then operates the on-off valve V2 to open to discharge the pure water (e.g., DIW) from the fixed nozzle 3 (see FIG. 4(f)). In FIG. 4(f), for the convenience of illustration, the fixed nozzle 3 is illustrated on the right side in FIG. 4(f).

The pure water discharged from the fixed nozzle 3 lands on the substrate W near the center, where the pure water does not hit the polishing tool 31 that is in contact with the center of the substrate W directly. The polishing tool turning mechanism 41 of the polishing arm 5 moves the polishing tool 31 from the standby position to above the center of the substrate W.

The control unit 71 then presses the polishing tool 31 against the rear surface of the substrate W being rotated while discharging pure water from the fixed nozzle 3 to the rear surface of the substrate W being rotated (polishing tool pressing step). That is, with the pure water being discharged from the fixed nozzle 3, the lift mechanism 39 of the polishing arm 5 presses the polishing tool 31 against the rear surface of the substrate W being rotated, by moving down the polishing tool 31. The polishing arm 5 includes a load sensor (load cell), not illustrated. The pressing load of the polishing tool 31 against the substrate W is controlled to 20 gf (gram weight), for example. To polish (grind) the rear surface of the substrate W with the polishing tool 31, the polishing tool 31 is rotated about the vertical axis AX2 by the electric motor 37.

The control unit 71 also moves the polishing tool 31 from the center of the substrate W to the perimeter of the substrate W while pressing the polishing tool 31 against the rear surface of the substrate W (see FIGS. 4(e) and 4(f)). When the polishing tool 31 reaches the perimeter of the substrate W, the lift mechanism 39 moves up the polishing tool 31. If the rinsing liquid/polishing process is to be repeated, the polishing tool turning mechanism 41 moves the polishing tool 31 above the perimeter of the substrate W to above the center of the substrate W.

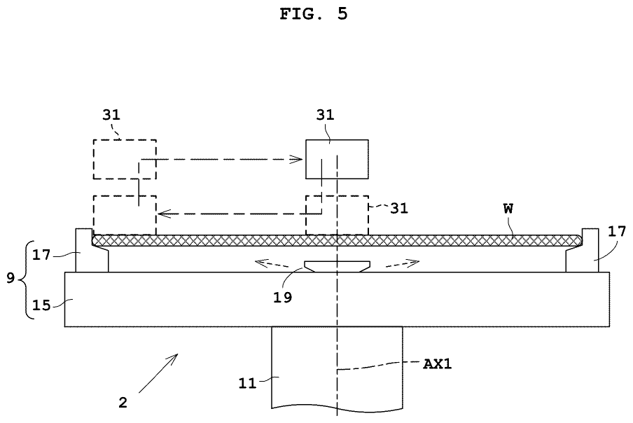

As illustrated in FIG. 5, one run of the rinsing liquid/polishing process includes moving the polishing tool 31 from the center of the substrate W to the perimeter of the substrate W while pressing the polishing tool against the rear surface of the substrate W being rotated, and moving the polishing tool 31 from the perimeter of the substrate W back to the center of the substrate W, with the polishing tool 31 separated from the rear surface of the substrate W. This rinsing liquid/polishing process is repeated for additional three times, for example. In other words, the rinsing liquid/polishing process is performed four times in total.

As a result, the polishing tool 31 removes the particle MT from the substrate W, and polishes the rear surface of the substrate W, including the scratches SRT2 and the like remaining from the etching of the FOM (see FIG. 6(e)). In addition, the unevenness (waviness and surface roughness) of the rear surface of the substrate W is smoothed out by the polishing. Furthermore, the etching process with the FOM has been performed before rinsing liquid/polishing process. This etching makes it easy to remove the particles (e.g., metal dust) buried in the rear surface of the substrate W. The rear surface of the substrate W is then actively polished (ground) using the polishing tool 31. The particles can be therefore removed more easily from the rear surface of the substrate W. After the rinsing liquid/polishing process is performed four times, the polishing arm 5 brings the polishing tool 31 back to the standby position.

### [Step S06] Rinsing Process

After performing rinsing liquid/polishing process four times, pure water is then discharged from the fixed nozzle 3 onto the rear surface of the substrate W being rotated. The rotation speed of the substrate W is, for example, 500 rpm. With this, the substrate W after the rinsing liquid/polishing process is rinsed off.

### [Step S10] Spin Dry

The on-off valve V2 is then operated to close, and the pure water stops being supplied from the fixed nozzle 3. The holding and rotating unit 2 then rotates the substrate W at a higher speed (for example, 1500 rpm). In this manner, the holding and rotating unit 2 performs a spin drying process for drying the substrate W.

### [Step S11] Stop Rotating Substrate

The holding and rotating unit 2 then stops rotating the substrate W. The control unit 71 also stops discharging the gas from the gas outlet 19, by operating the on-off valve V1. The holding and rotating unit 2 then releases the substrate W having been held thereby. The transfer robot, not illustrated, picks up the substrate W having the rear surface cleaned, from the holding and rotating unit 2, and transfers the substrate W to a next destination.

According to this embodiment, with the FOM being discharged to the rear surface of the substrate W, the silicon becomes oxidized with the ozonated water, and the oxide film (SiO) is etched with hydrofluoric acid. In this manner, the fine scratches and dents on the rear surface of the substrate W can be removed. Furthermore, the part around the particle MT having been firmly attached to the rear surface of the substrate W is etched by the FOM; therefore, the particle MT are made more easily removable. The rear surface of the substrate W is then actively polished (ground) using the polishing tool 31. In this manner, the particle MT can be removed more easily from the rear surface of the substrate W. Hence, a larger proportion of chuck marks formed on the substrate W can be removed.

In addition, with the chemical liquid mixture (FOM), the surface roughness of the rear surface of the substrate W can be reduced. Therefore, it is possible to alleviate the load in the polishing process for removing the scratches SRT2 and the like remaining after the etching with the chemical liquid mixture.

### SECOND EMBODIMENT

A second embodiment of the present invention will now be described with reference to drawings. Note that redundant descriptions with those in the first embodiment will be omitted. FIG. 7 is a flowchart illustrating the operation of the substrate processing apparatus 1 according to the second embodiment.

According to the first embodiment, after the rinsing liquid/polishing process in step S05 and the rinsing process in step S06 are performed, the spin drying is performed in step S10. In this regard, after the rinsing liquid/polishing process (including the polishing tool pressing step and the polishing tool moving step) in step S05 and the rinsing process in step S06, the process of discharging the FOM (step S07) may be performed again, as illustrated in FIG. 7. The operation of the second embodiment is performed by the substrate processing apparatus 1 according to the first embodiment illustrated in FIGS. 1 and 2.

The operation of the substrate processing apparatus 1 according to the second embodiment will now be described with reference to the flowchart of FIG. 7. Note that steps S01 to S06 and steps S10 and S11 according to the second embodiment illustrated in FIG. 7 are the same as steps S01 to S06 and steps S10 and S11 according to the first embodiment, respectively.

### [Step S07] Second Discharging of FOM

In steps S07 to S09, the substrate W is rotated at, for example, 800 rpm. After performing the rinsing process in step S06, the nozzle turning mechanism 57 of the chemical liquid arm 7 moves the chemical liquid nozzle 51 from the standby position of the substrate W to above the center of the substrate W. The control unit 71 then causes the chemical liquid nozzle 51 to discharge FOM (chemical liquid mixture of hydrofluoric acid and ozonated water) onto the rear surface (top surface) of the substrate W being rotated (see FIGS. 4(a) and 4(b)). At this time, the on-off valve V3 is operated to open, and the two on-off valves V4 and V5 are operated to close. The FOM having landed on the substrate W, which is being rotated, spreads across the entire surface of the substrate W, and extra FOM is removed off of the substrate W.

In the rinsing liquid/polishing process in step S05, the polishing tool 31 may leave some scratches on the rear surface of the substrate W. Such a scratch may become a cause of defocus in the EUV step. Therefore, in this step S07, the polished surface (rear surface) is etched again, by discharging the FOM onto the rear surface of the substrate W being rotated. The ozonated water in the FOM oxidizes the silicon of the polished surface, and the oxide film (SiO₂) is then removed. With this, it is possible to remove the scratches formed in the polishing process. In addition, it is possible to reduce the surface roughness of the polished surface. In FIG. 6(b), the surface roughness of the polished surface is reduced probably for the reason that the oxide film is formed more easily on the rear surface of the substrate W than inside the scratch.

The FOM may be discharged over a shorter time period in step S07, than the time period for which the FOM is discharged in step S02, when the scratches formed in the polishing process are smaller than the scratches in the chuck marks.

### [Steps S08 and S09] Discharge Ozonated Water and Rinsing Process

After performing the second FOM discharging process (etching process), the control unit 71 discharges the ozonated water from the chemical liquid nozzle 51 onto the rear surface of the substrate W being rotated, for a predetermined time period (step S08). The control unit 71 then discharges pure water from the chemical liquid nozzle 51 onto the rear surface of the substrate W being rotated, for a predetermined time period. After performing the rinsing process in step S09, the drying process in step S10 is performed.

According to this embodiment, after the polishing processing (the polishing tool pressing step and the polishing tool moving step), the control unit 71 discharges the FOM again, from the chemical liquid nozzle onto the rear surface of the substrate being rotated (second chemical liquid mixture discharging step). With the polishing processing, although the rear surface of the substrate W can be planarized while removing the chuck marks on the rear surface of the substrate W, there is a possibility that the polishing tool 31 leaves some scratches. Therefore, by discharging the FOM onto the rear surface of the substrate W after the polishing process, the scratches formed by the polishing tool 31 can be removed. In addition, because the scratches formed by the polishing tool 31 can be removed by the FOM in step S02, the configuration of liquid supply can be simplified.

The present invention is not limited to the embodiments described above, and following modifications are still possible.
(1) In the second FOM discharging step (step S07) according to the second embodiment described above, while the chemical liquid nozzle 51 is discharging the FOM, the control unit 71 keeps the chemical liquid nozzle 51 above the center of the substrate W, without moving the chemical liquid nozzle in the horizontal direction. Therefore, the FOM is kept being discharged above the center of the substrate W (fixed point). In this regard, in the second FOM discharging step, the control unit 71 may move the chemical liquid nozzle 51 between above the center of the substrate W and above the perimeter of the substrate W, while the chemical liquid nozzle 51 is discharging the FOM.

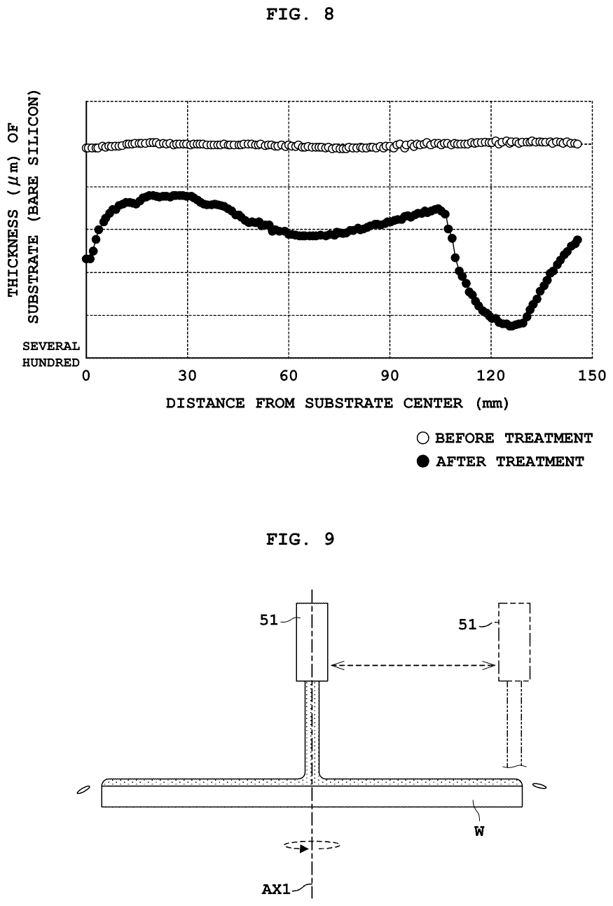

FIG. 8 is a graph illustrating thicknesses of the substrate W before and after the etching process using the FOM. In FIG. 8, the horizontal axis represents the distance from the center of the substrate W (150 mm at the maximum), and the vertical axis represents the thickness of the substrate W. For the etching process indicated FIG. 8, a silicon substrate with a diameter of 300 mm was used. In the etching process illustrated in FIG. 8, the FOM was kept discharged onto the center of the substrate W being rotated, and then the FOM is kept discharged onto the perimeter of the substrate W. As the results in FIG. 8 indicates, when the FOM is kept being discharged at fixed points that are at the center and the perimeter of the substrate W, the silicon substrate becomes thinner at the center and the perimeter of the substrate W. Therefore, the rear surface of the substrate W, having already been planarized by the rinsing liquid/polishing process, may end up becoming irregular.

To address this issue, as illustrated in FIG. 9, while the chemical liquid nozzle 51 is discharging the FOM, the nozzle turning mechanism 57 moves the chemical liquid nozzle 51 between above the center of the substrate W and above the perimeter of the substrate W. As a result, with the etching process using the FOM, the scratches resultant of the polishing process can be removed, while preventing irregularities from being formed on the rear surface of the substrate W having already planarized by the rinsing liquid/polishing process.

While the chemical liquid nozzle 51 is discharging the FOM, the chemical liquid nozzle 51 may be moved back and forth between above the center of the substrate W and above the perimeter of the substrate W, or the chemical liquid nozzle 51 may be moved only forth.

According to the present modification, scratches caused by the polishing tool 31 can be removed; however if the chemical liquid mixture from the chemical liquid nozzle 51 is kept landing on the same position of the rear surface of the substrate W, etching at that position may proceed too far. Therefore, by moving the position of the chemical liquid mixture, it is possible to prevent the etching from proceeding locally on the rear surface of the substrate W having been planarized by the polishing process.
(2) In the FOM discharging step (step S02) of each of the embodiments and the modification (1) described above, while the chemical liquid nozzle 51 is discharging the FOM, the control unit 71 keeps the chemical liquid nozzle 51 above the center of the substrate W, without moving the chemical liquid nozzle 51 in the horizontal direction. In this regard, in the manner as in the modification (1), while the chemical liquid nozzle 51 is discharging the FOM in step S02 in FIG. 3 or FIG. 7, the control unit 71 may move the chemical liquid nozzle 51 between above the center of the substrate W and above the perimeter of the substrate W.
(3) In each of the embodiments and modifications described above, the rinsing liquid/polishing process is performed four times in total in step S05, but the present invention is not limited thereto. In other words, the number of times of the rinsing liquid/polishing process may be any number that is one or more.
(4) In each of the embodiments and modifications described above, the control unit 71 moves the polishing tool 31 from the center of the substrate W to the perimeter of the substrate W while pressing the polishing tool 31 against the rear surface of the substrate W. The direction in which the polishing tool 31 for polishing the rear surface of the substrate W is moved is not limited to the direction from the center of the substrate W toward the perimeter of the substrate W (outward direction). The direction in which the polishing tool 31 for polishing is moved may be, for example, a direction from the perimeter of the substrate W toward the center of the substrate W (inward direction), as required. The direction of the movement may be both of the outward direction and the inward direction.
(5) In each of the embodiments and modifications described above, the fixed nozzle 3 and the chemical liquid nozzle 51 discharge pure water as the rinsing liquid, but the rinsing liquid is not limited to the pure water. The rinsing liquid may be, for example, carbonated water, hydrogen water, or electrolytic ion water.
(6) In each of the embodiments and modifications described above, the polishing tool turning mechanism 41 as the polishing tool moving mechanism turns the polishing tool 31 about the vertical axis AX3. In this regard, the polishing tool moving mechanism may also be configured to move the polishing tool 31 linearly in the horizontal direction. The polishing tool moving mechanism may be also configured to move the polishing tool 31 in the X direction and the Y direction. The same applies to the chemical liquid nozzle 51.
(7) In each of the embodiments and modifications described above, the chemical liquid nozzle 51 discharges the FOM, the ozonated water, or the pure water, selectively. In this regard, ozonated water and pure water may be discharged from separate nozzles.
(8) In each of the embodiments and modifications described above, the resin body of the polishing tool 31 is not soft like a sponge, and is a member having hardness with which the member slightly deforms upon being pressed. In this regard, the resin body may be like a sponge.
(9) In each of the embodiments and modifications described above, the ozonated water discharging step in step S03 is performed after the FOM discharging step in step S02. In this regard, the ozonated water discharging step in step S03 after the FOM discharging step in step S02 may be omitted.

### REFERENCE SIGNS LIST

1 substrate processing apparatus
2 holding and rotating unit
3 fixed nozzle
5 polishing arm
7 chemical liquid arm
31 polishing tool
39 lift mechanism
41 polishing tool turning mechanism
51 chemical liquid nozzle
57 nozzle turning mechanism
71 control unit

1. A substrate processing method comprising:
a substrate rotating step of rotating a substrate made of silicon in a horizontal orientation;
a chemical liquid mixture discharging step of causing a chemical liquid nozzle to discharge a chemical liquid mixture including hydrofluoric acid and ozonated water onto a rear surface of the substrate being rotated;
a polishing tool pressing step of pressing a polishing tool that has a resin body including dispersed abrasive grains, against the rear surface of the substrate being rotated, while causing a rinsing liquid nozzle to discharge a rinsing liquid onto the rear surface of the substrate being rotated, after the chemical liquid mixture discharging step; and
a polishing tool moving step of moving the polishing tool between a center of the substrate and a perimeter of the substrate while the polishing tool pressing step is being performed.

2. The substrate processing method according to claim 1, further comprising a second chemical liquid mixture discharging step of causing the chemical liquid nozzle to discharge the chemical liquid mixture onto the rear surface of the substrate that is being rotated, again, after the polishing tool pressing step and the polishing tool moving step.

3. The substrate processing method according to claim 2, wherein, in the second chemical liquid mixture discharging step, the chemical liquid nozzle is moved between above the center of the substrate and above the perimeter of the substrate while the chemical liquid nozzle is discharging the chemical liquid mixture.

4. A substrate processing apparatus comprising:
a holding and rotating unit that holds and rotates a substrate made of silicon in a horizontal orientation;
a chemical liquid nozzle that discharges a chemical liquid mixture including hydrofluoric acid and ozonated water;
a rinsing liquid nozzle that discharges a rinsing liquid;
a polishing tool that has a resin body including dispersed abrasive grains;
a polishing tool moving mechanism that moves the polishing tool; and
a control unit, wherein
the control unit causes the holding and rotating unit to rotate the substrate, the control unit causes the chemical liquid nozzle to discharge the chemical liquid mixture onto a rear surface of the substrate being rotated;
after the chemical liquid mixture is discharged, the control unit causes the polishing tool moving mechanism to press the polishing tool against the rear surface of the substrate being rotated, while causing the rinsing liquid nozzle to discharge the rinsing liquid onto the rear surface of the substrate being rotated, and
the control unit further causes the polishing tool moving mechanism to move the polishing tool between a center of the substrate and a perimeter of the substrate while pressing the polishing tool against the rear surface of the substrate being rotated.

5. The substrate processing apparatus according to claim 4, wherein
after performing a polishing operation by moving the polishing tool while pressing the polishing tool against the rear surface of the substrate being rotated, the control unit further causes the chemical liquid nozzle to discharge the chemical liquid mixture onto the rear surface of the substrate being rotated.

6. The substrate processing apparatus according to claim 5, further comprising:
a chemical liquid nozzle moving mechanism that moves the chemical liquid nozzle, wherein
after performing the polishing operation, the control unit further causes the chemical liquid nozzle moving mechanism to move the chemical liquid nozzle between above the center of the substrate and above the perimeter of the substrate while the chemical liquid nozzle is discharging the chemical liquid mixture.
